(19) United States
(12) Patent Application Publication
(10) Pub. No.: US 2018/0233316 A1
(43) Pub. Date: Aug. 16, 2018

(54) ELECTRON BEAM PROJECTOR WITH LINEAR THERMAL CATHODE

(71) Applicant: STATE ENTERPRISE "INTERNATIONAL CENTER FOR ELECTRON BEAM TECHNOLOGI, Kyiv (UA)

(72) Inventors: Kostyantyn Yu YAKOVCHUK, Kyiv (UA); Vitalii O BARSKOV, Kyiv (UA); Ivan G. KLYMENKO, Kyiv (UA); Yuriy E. RUDOY, Kyiv (UA)

(21) Appl. No.: 15/751,606

(22) PCT Filed: Apr. 5, 2017
(86) PCT No.: PCT/UA2017/000034

§ 371 Date: Feb. 9, 2018

(30) Foreign Application Priority Data
Oct. 31, 2016 (UA) A 2016 10948

(51) Int. Cl. H01J 29/48; H01J 37/065; H01J 37/305; H01J 29/82; H01J 29/04

(52) U.S. Cl. CPC H01J 29/488; H01J 37/065; H01J 2229/481; H01J 29/82; H01J 29/04; H01J 37/305

(57) ABSTRACT

An electron beam projector with a linear thermal cathode (7) for electron beam heating consists of a beam guide (1) which comprises a deflecting electromagnetic system (2) and accommodates an accelerating anode (3) fixed on it by a posts (10), where anode is connected by a high-voltage insulators (4) through a cathode plate (5) to a cathode assembly (6), that includes the linear thermal cathode (7) fastened in a cathode holders (8), and a focusing electrode (9). The accelerating anode (3) comprises a plate (11) rigidly fastened to it for hermetical separation of the cathode (7) and the beam guide (1) parts of the projector, wherein the common optical axis of a cathode assembly (6) and the accelerating anode (3) is deflected from a beam guide optical axis by an angle a that is equal to 10÷30°.

### FIELD OF THE INVENTION

The invention pertains to apparatuses of electron beam technology, and more specifically, to electron beam projectors (guns) that generate the electron beam which is applied for heating, melting and evaporation of materials in vacuum or reactive gas atmosphere.

### BACKGROUND OF THE INVENTION

Emergence and wide introduction of electron beam technology for melting and evaporation of different materials is associated, primarily, with development and improvement of the key element of this technology, namely electron beam projector (or gun) which generates the electron beam. At present two types of electron beam projectors have become widely accepted, which are used for evaporation and melting of materials in vacuum, namely axial, forming an axially symmetrical flow, and flat beam with linear thermal cathode, in which the primary flat electron beam is transformed into a cylindrical one [B. A. Movchan, I. S. Malashenko “Heat-resistant coatings, deposited in vacuum”.—Kiev, Naukova Dumka, 1983.-230 p.]. Electron beam projectors with a linear cathode of 100 up to 150 kW power are small-sized, easy to operate and are extensively applied in commercial electron beam units (4-8 guns in one unit) for various purposes, used for producing different coatings and materials both in vacuum environment, and in reactive gas atmosphere.

Electron beam projectors with linear thermal cathode developed at the E. O. Paton Electric Welding Institute of the NAS of Ukraine [B. A. Movchan, I. S. Malashenko “Heat-resistant coatings, deposited in vacuum”.—Kiev, Naukova Dumka, 1983.-230 p.] became the most widely accepted. The main design element of such electron beam projectors is the beam guide, comprising the deflecting electromagnetic system (electromagnetic coils for electron beam focusing and deflection), with accelerating anode attached to it, which is connected by high-voltage insulators through cathode plate to cathode assembly, which comprises linear thermal cathode, fixed in two cathode holders, and focusing electrode positioned coaxially with it. Beam guide and accelerating anode are water-cooled structures of a rectangular or round shape with an opening (slot) in the center for electron beam passage, wherein linear thermal cathode (cathode assembly) and accelerating anode have a common optical axis, which coincides with beam guide optical axis (i.e. with its vertical axis). Trajectory of movement of electron beam inside this structure coincides with common optical and geometrical axis of aligned assemblies of electron beam projector, namely cathode assembly, accelerating anode and beam guide. Electron beam deflection from the above-mentioned optical axis is performed inside the beam guide by deflecting electromagnetic system. Such electron beam projectors can deflect the electron beam at its exit from the beam guide by 25÷45 degrees from its optical axis, can be positioned at considerable distance from materials being heated, and can be located in individual vacuum chambers, having individual pumping devices. This allows applying them with success in commercial electron beam units for operation both in vacuum environment and in reactive gas atmosphere.

The main problem of the majority of known electron beam projectors with linear thermal cathode is short duration of stable operation of linear thermal cathode, particularly, in the atmosphere of reactive gases (for instance oxygen) that necessitates its frequent replacement, as well as insufficient stability of assigned electron beam parameters (stability of required size of focal spot on the surface of materials being heated) during long-term operation of electron beam projector.

Short duration of linear thermal cathode operation in currently available electron beam projectors is due to such adverse phenomena as:
intensive ion bombardment of linear thermal cathode, which results from atom ionization that is the most pronounced at high pressure of residual or reactive gases in the vacuum chamber during the technological process;
deposition on the surface of linear thermal cathode of atoms and molecules of metal or ceramic materials that evaporate (melt) during the technological process, which penetrate through the beam guide and accelerating anode, and their further interaction with thermal cathode material that leads to changing of its physico-mechanical properties and fracture;
change of geometrical shape of linear thermal cathode and its position relative to focusing electrode under the impact of cyclic processes of heating/cooling in operation with further deterioration of generated electron beam parameters.

Improvement of modern electron beam projectors is aimed at extension of operating life of linear thermal cathodes due to minimizing the above negative phenomena.

Ukrainian patent no. 40644 “Electron gun with linear thermal cathode for electron beam heating” of 15 Aug. 2001, authors being M. I. Grechaynuk, O. K. Dyatlova, P. P. Kucherenko, E. L. Piyuk, proposes a design of electron gun with linear thermal cathode for electron beam heating, which comprises accelerating anode, connected by high-voltage insulators to cathode assembly, which includes the case, flat insulator, mounted in the above case, linear thermal cathode, mounted in two cathode holders on the case, one of them being mobile and connected to the case through flat insulator by fasteners, using at least two current-conducting springs, focusing electrode with terminal current lead for applying to it a controllable negative potential relative to coaxially positioned linear thermal cathode and enclosing the above linear thermal cathode by its two-sided surface, terminal leads for supplying filament current, characterized in that the mobile cathode holder is hingedly connected to the cathode assembly case. As stated by patent authors, such a design provides higher stability of the position of linear thermal cathode relative to focusing electrode that improves operating life of linear thermal cathode and stability of electron beam shape.

In U.S. Pat. No. 6,455,990 “Apparatus for electron gun employing a thermoionic electron source” of 24 Sep. 2002, the author, B. E. Mensinger, proposed a design of electron beam projector, in which a diaphragm—a slotted plate, is placed between accelerating anode and linear thermal cathode that protects linear cathode surface from ion bombardment and extends its operating life. Here, the plate is in contact with linear thermal cathode surface, being its integral part. The prevailing material for diaphragm-plate manufacturing is graphite.

The closest to claimed invention in its technical essence, is the design of electron beam projector described in Ukrainian patent no. 43927 “Electron gun with linear thermal cathode for electron beam heating” of 15 Jan. 2002, the authors being B. O. Movchan, O. Ya. Gavrilyuk. Proposed electron beam gun with linear thermal cathode for electron beam heating comprises the beam guide with fastened on it accelerating anode, connected by high-voltage insulators through cathode plate to cathode assembly that includes linear thermal cathode fastened in two cathode holders, and focusing electrode, in which, according to the invention, the beam guide is separated from accelerating anode by posts that ensure rigid fastening of accelerating anode on beam guide and creating a space between them; accelerating anode incorporating a plate rigidly connected to it, for hermetically separating cathode and beam guide parts of the gun.

Such a design, in which the cathode and beam guide parts are hermetically separated, and accelerating anode is removed from the beam guide, provides, as stated by the authors, an significant increase of cathode resistance to damage from ion bombardment, particularly when operating in units with reactive gas application.

The main disadvantage of this design, similar to all the other known electron beam projectors with linear thermal cathodes, is insufficient protection of linear thermal cathode surface from deposition of atoms and molecules of materials that evaporate or melt during the technological process, and from ion bombardment that is due to linear thermal cathode (cathode assembly), accelerating anode and beam guide having a common optical (geometrical) axis. Flow of electrons which is generated by linear thermal cathode, is accelerated during movement along this axis in the direction towards the accelerating anode, passes through it and then passes through beam guide, being deflected from optical axis in it, while changing its shape and movement trajectory under magnetic field impact. Such a design of available electron beam projectors cannot provide reliable protection from the above-mentioned negative phenomena, as linear thermal cathode, accelerating anode and beam guide have a common optical (geometrical) axis (i.e. are located on one straight line). Atoms/molecules of evaporated substances or ions that penetrated into the beam guide, further penetrate unhindered through accelerating anode to the surface of linear thermal cathode and precipitate there, or bombard its surface. Change of electron beam projector position in electron beam units with the purpose of eliminating direct optical contact between the vapour flow and surface of linear thermal cathode, similar to removing accelerating anode from beam guide, does not have any essential effect in the case of a common optical axis of linear thermal cathode-accelerating anode-beam guide.

It is rational to perform further upgrading of electron beam projector towards improving the protection of linear thermal cathode surface from the above negative phenomena, which arise in operation of electron beam projectors, by means of shifting linear thermal cathode surface from beam guide optical axis, i.e. by deflecting the common optical axis of linear thermal cathode (cathode assembly) and accelerating anode from beam guide optical axis.

### SUMMARY

The objective of this invention is creation of electron beam projector that is devoid of the above drawbacks and provides an essential extension of operating life of linear thermal cathode.

The defined objective is achieved by proposing an electron beam projector with linear thermal cathode for electron beam heating that comprises beam guide, which includes deflecting electromagnetic system, and accommodates accelerating anode fastened on it by posts, which is connected by high-voltage insulators through cathode plate to cathode assembly that incorporates linear thermal cathode, fastened in cathode holders, and focusing electrode; accelerating anode comprising a rigidly connected to it plate for hermetical separation of the cathode and beam guide parts of the projector, wherein, according to the invention, the common optical axis of cathode assembly and accelerating anode is deflected from beam guide optical axis by angle α that is equal to 10÷30°.

In the known designs of electron beam projectors with linear thermal cathode, plane-parallel electron beam, formed by electric field in the space between linear cathode and accelerating anode, moves along a common optical axis, which coincides with geometrical axis of linear cathode-accelerating anode-beam guide. Thus, it is impossible to reliably protect linear thermal cathode from bombardment by ion flow or its working surface from being hit by atoms and molecules of vapour flow of materials that melt or evaporate.

In the apparatus according to the invention, this possibility of protection of linear thermal cathode is provided due to deflection of optical axis of linear cathode-accelerating anode, along which the flow of electrons generated by linear thermal cathode, is accelerated, from beam guide optical axis (its geometrical axis) by changing the position (inclination) of cathode assembly and accelerating anode relative to beam guide.

Owing to such a design, the life of linear thermal cathode becomes significantly longer, due to its removal from the zone of bombardment by the ion flow, and prevention of its working surface being hit by atoms and molecules of vapour flow of materials that are melted or evaporated.

### BRIEF DESCRIPTION OF THE DRAWINGS

Technical essence and principle of operation of the invention are explained on examples of implementation with reference to appended drawings.

FIG. 1 shows the schematic of partial transverse (a) and longitudinal (b) cross-sections of electron beam projector with linear thermal cathode, according to the invention.

FIG. 2 shows the schematic of partial cross-section of a traditional electron beam projector with linear thermal cathode.

FIG. 3 shows the graph of operating life of linear thermal cathode at testing in electron beam projector according to the invention, depending on the angle of inclination of optical axis of cathode assembly and accelerating anode relative to optical axis of beam guide at evaporation of metal ingots of Ni-18% Cr-12% Al-0.3% Y of 68.5 mm diameter at 1.5 A current.

FIG. 4 presents the appearance of working surface of linear thermal cathode after operation in the traditional electron beam projector (a) and in electron beam projector (b) according to the invention, after evaporation of ceramic ingots of ZrO₂-8% Y₂O₃ type of 68.5 mm diameter at 1.6 A current for 32 and 96 hours, respectively.

### DETAILED DESCRIPTION OF THE INVENTION

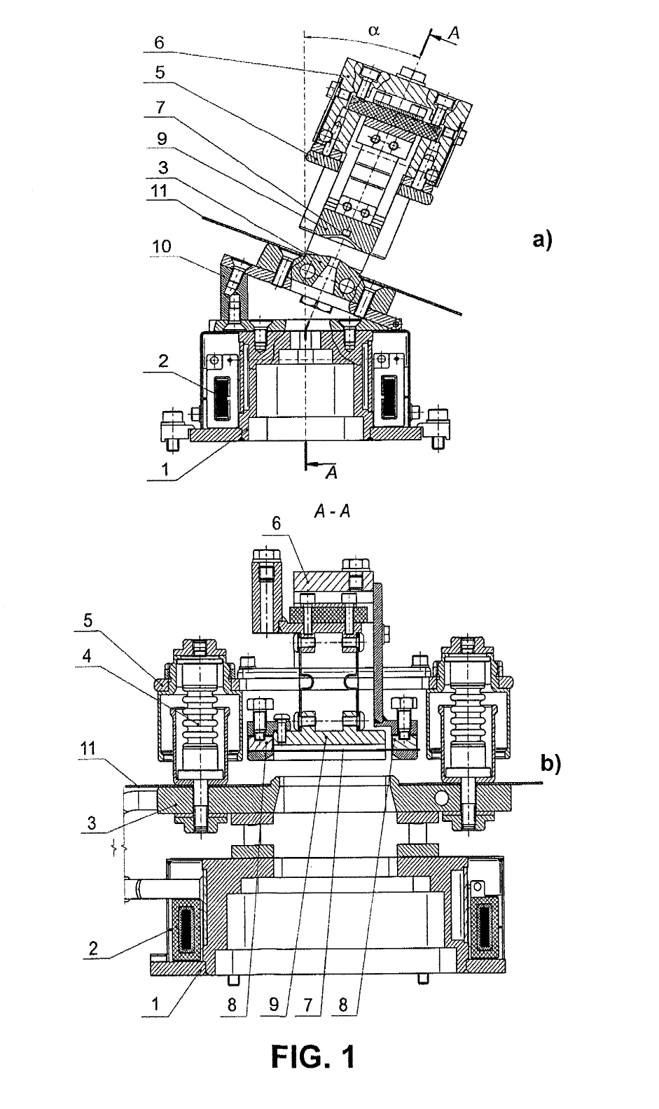

Electron beam projector with linear thermal cathode (FIG. 1) for electron beam heating is proposed, which comprises beam guide 1, including deflecting electromagnetic system 2, with accelerating anode 3 fastened on beam guide by posts 10, which is connected by high-voltage insulators 4 through cathode plate 5 to cathode assembly 6 that incorporates linear thermal cathode 7, fixed in cathode holders 8, and focusing electrode 9; accelerating anode 3 including rigidly connected to it plate 11 for hermetical separation of cathode and beam guide parts of the projector, wherein according to the invention, the common optical axis of cathode assembly and accelerating anode is deflected from beam guide optical axis by angle α that is equal to 10÷30 degr.

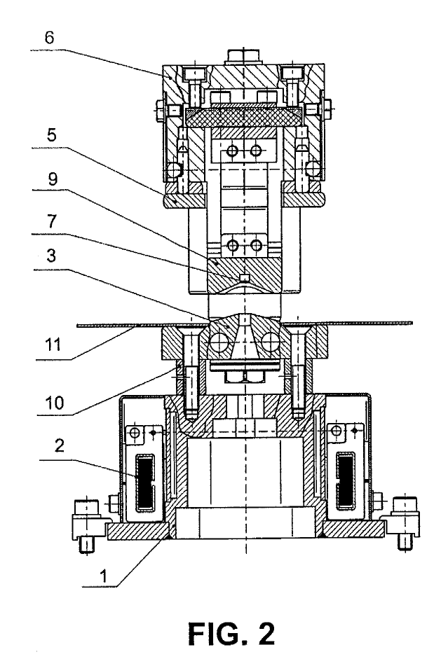

As is seen from the appended drawings, and the given description, in the proposed design of electron beam projector with linear thermal cathode, unlike the real design of the prototype (FIG. 2), cathode assembly and accelerating anode are positioned at angle α to beam guide vertical axis, i.e. their common optical axis is deflected from beam guide optical axis by angle α that is equal to 10÷30 degr.

The apparatus operates as follows:

At voltage application to electron beam projector from power source, filament current, passing through cathode holders 8 and linear thermal cathode 7, heats it up to the temperature at which thermoelectronic emission occurs. At the same time, high voltage (negative potential) from high-voltage power source is applied to cathode assembly 6. Electrons which flew out from the surface of linear thermal cathode, are accelerated along the optical axis of cathode assembly-accelerating anode in the electric field applied between cathode assembly 6 and accelerating anode 3, which are electrically separated by high-voltage insulators 4. Having passed through accelerating anode, the electron beam moves by inertia along a common optical axis of cathode assembly-accelerating anode, penetrating into beam guide 1 at angle α to its optical axis. Deflecting electromagnetic system 2 provides deflection of electron beam trajectory by the required angle, when it leaves the beam guide. Here, the main parameters of the beam (focal spot size, specific power, etc.) and its control along two coordinates remain unchanged.

Position of linear thermal cathode in the proposed design ensures minimizing the negative impact of ion flow on it and prevents penetration of atoms and molecules of evaporated materials on its surface, when conducting the technological processes of melting and evaporation. This provides an essential (3-3.2 times) extension of service life of linear thermal cathode, and higher stability of electron-optical parameters. The greatest effect of application of the claimed electron beam projector with linear thermal cathode is achieved in the cases when long-term operation of electron beam unit without breaking vacuum in the chamber or thermal cathode replacement is required in the processes of melting and evaporation in the atmosphere of reactive gases, for instance oxygen.

### Example 1

Electron beam projector of PE-123 type of 60 kW power with standard linear thermal cathode (tungsten plate of 100×3×0.6 mm size) was mounted in electron beam unit of UE-207 type and was used for evaporation of ingots of MCrAlY alloy (Ni-18% Cr-12% Al-0.2% Y) of 68.5 mm diameter, placed into water-cooled copper crucible of 70 mm diameter. Distance from beam guide plane to crucible surface was 680 mm. Angle of deflection of common optical axis of cathode assembly and accelerating anode relative to beam guide optical axis changed in the range from 0° to 30°. Pressure of residual gases in the unit work chamber during ingot evaporation was on the level of 2×10⁻² Pa, accelerating voltage was 20 kV, evaporation beam current was 1.5 A.

Time of linear thermal cathode operation at evaporation current was recorded, testing was stopped after change (violation) of electron beam shape, at which conducting the evaporation process became impossible.

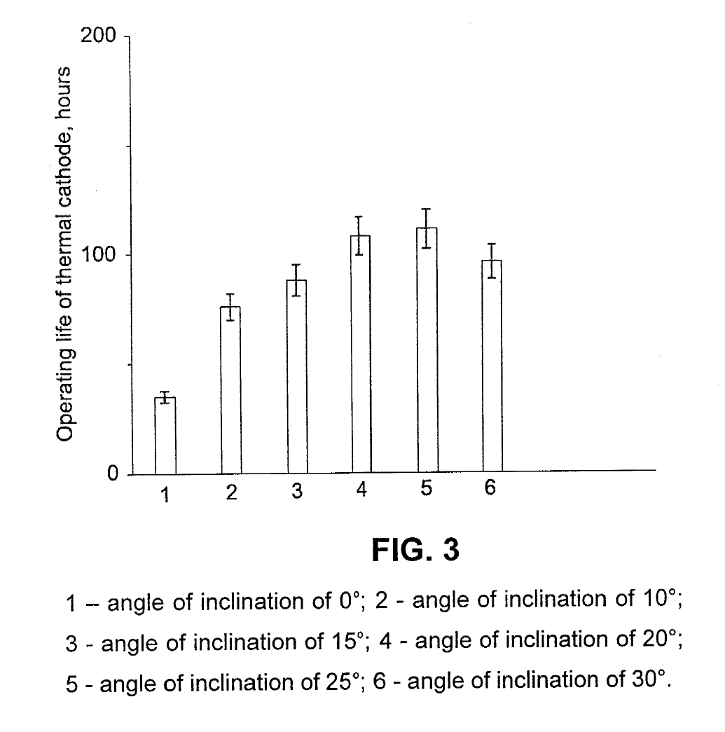

Results of performed testing, presented in FIG. 3, show that maximum extension of linear thermal cathode life is achieved at angles of deflection of common optical axis of cathode assembly and accelerating anode relative to beam guide optical axis in the range of 20÷25°.

### Example 2

Electron beam projector of PE-123 type of 60 kW power with standard linear thermal cathode (tungsten plate of 100×3×0.6 mm) was mounted in electron beam unit of UE-202 type and was used for evaporation of ceramic ingots of ZrO₂-8% Y₂O₃ type of 68.5 diameter, placed into water-cooled copper crucible of 70 nm diameter.

Angle of deflection of common optical axis of cathode assembly and accelerating anode relative to beam guide optical axis was equal to 20°, angle of deflection of electron beam from electronic optical axis of beam guide at its exit from beam guide was also equal to 20°. Residual gas pressure in the unit work chamber during ingot evaporation was on the level of 5×10⁻² Pa, accelerating voltage was 20 kV, beam current for evaporation was 1.6 A. During evaporation, oxygen in the quantity of approximately 200 cm³/min., was supplied into the unit work chamber. Recorded average time of operation of linear thermal cathode of electron beam projector at this current was 95 hours. Testing was interrupted in connection with deterioration of beam geometrical parameters, making stable evaporation impossible.

Used as basic values for comparison were the results of similar testing of standard linear thermal cathode of the same dimensions of traditional electron beam projector of PE-123 type, wherein optical axis of cathode assembly, accelerating anode and beam guide coincided, and which was mounted in electron beam unit UE-202 (positions of all tested guns in UE-202 unit and all technological parameters of ingot evaporation were identical).

Recorded average time of operation of linear thermal cathode of traditional electron beam projector was 30 hours; testing was interrupted in connection with deterioration of beam geometrical parameters, making stable evaporation impossible.

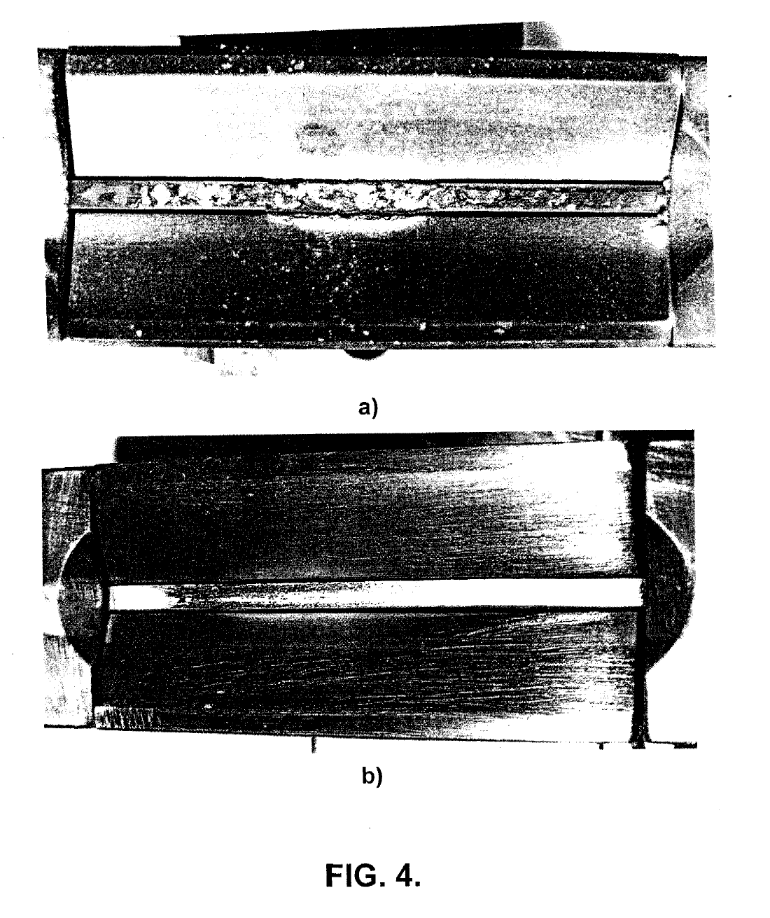

Appearance of linear thermal cathodes after testing of traditional electron beam projector and claimed electron beam projector is shown in FIG. 4. A characteristic feature of damage of the surface of linear thermal cathode of traditional electron beam projector is erosion damage in thermal cathode central zone and deposition of evaporation material (zirconia-based ceramics) on its surface. Surface of linear thermal cathode of electron beam projector, which is claimed, had no traces of evaporation material, just a slight impact of ion bombardment was observed along thermal cathode surface.

Above-mentioned positive effect is achieved owing to positioning of cathode assembly and accelerating anode so that their common electronic optical axis is deflected at an angle to electronic optical axis of beam guide, so that the surface of linear thermal cathode is removed from the zone, wherein intensive ion bombardment and deposition of evaporation materials are observed.

1. Electron beam projector with linear thermal cathode for electron beam heating that comprises beam guide, which includes deflecting electromagnetic system, with fastened to beam guide by posts accelerating anode, which is connected by high-voltage insulators through cathode plate to cathode assembly that incorporates linear thermal cathode, fastened in cathode holders, and focusing electrode; accelerating anode incorporating rigidly connected to it plate for hermetical separation of cathode and beam guide parts of the projector, wherein cathode assembly, accelerating anode and beam guide are positioned so that the common optical axis of cathode assembly and accelerating anode is deflected from beam guide optical axis by angle α that is equal to 10÷30°.
